(19) United States
(12) Patent Application Publication
(10) Pub. No.: US 2004/0184236 A1
(43) Pub. Date: Sep. 23, 2004

(54) Central processing unit (CPU) heat sink module

(76) Inventor: Kuang-Yao Lee, Taipei City (TW)

Correspondence Address: BIRCH STEWART KOLASCH & BIRCH, PO BOX 747, FALLS CHURCH, VA, 22040-0747, US

(21) Appl. No.: 10/391,807

(22) Filed: Mar. 20, 2003

(51) Int. Cl. H05K 7/20

(52) U.S. Cl. 361/697

(57) ABSTRACT

A central processing unit (CPU) heat sink module disposed under a central processing unit (CPU) and a motherboard comprises a conductive member disposed under the motherboard corresponsive to the position of the central processing unit (CPU), and a heat sink disposed on the conductive member, so that the conductive member rapidly transfers the heat source produced by the central processing unit (CPU) to the heat sink thereunder, and effectively disperses the heat source by the heat sink.

### FIELD OF THE INVENTION

The present invention relates to a central processing unit (CPU) heat sink module, more particularly to a heat sink module using a conductive member and a heat sink to rapidly disperse the heat source of the central processing unit (CPU).

### BACKGROUND OF THE INVENTION

In the area of computer products, heat dispersion is always a problem bothering computer users; particularly, the overheating of a computer often causes system failure or makes the computer unable to operate. Therefore, computer manufacturers try very hard to solve such heat dispersion problem. The prior art heat dispersion device includes heat sinks and fans, wherein the heat sink is a device having many metal heat dispersion fins on its surface, and these metal fins are individually perpendicular to the surface of the heat sink. A common passive heat sink can increase the surface area for heat dispersion, and the objective of such heat sink is to increase the area of heat dispersion. Of course, the heat can also be removed by the surrounding airflow, and the purpose of using fans is to promote the dispersion of heat. In general, a fan is used to blow at the heat sink and carry the heat away.

The operation of a computer system depends on the performance of the central processing unit (CPU); at present, there are two main trends in central processing unit (CPU) developments; one emphasizes on a light and compact design, and the other on high performance. As the timing of the central processing unit (CPU) increases and the volume decreases, the heat generating density rises rapidly. If we cannot provide an effective way for dispersing the heat, it may affect the performance and reliability of central processing unit (CPU), or even shorten the life of use. Traditionally, a central processing unit (CPU) usually comes with a fan or a heat sink to increase the heat dispersion area on one hand, and blow the heat source away from the central processing unit (CPU). Alternatively, a heat dispersion paste is coated on the surface of the central processing unit (CPU) for the purpose of dispersing heat. However, the above heat dispersion methods usually neglect the fact that the heat source of the central processing unit (CPU) focuses at the contact end under the central processing unit (CPU), and the fan or heat sink mainly removes the heat on the top of the central processing unit (CPU), but is unable to eliminate the heat source produced at the contact end.

### SUMMARY OF THE INVENTION

The primary objective of the present invention is to solve the aforementioned problems and eliminate the drawbacks of cited prior art by effectively removing the heat source at the contact end under the central processing unit (CPU).

To achieve the foregoing objective, the central processing unit (CPU) heat dispersion module according to the present invention is disposed under a central processing unit (CPU) and a motherboard, and said heat dispersion module comprises a conductive member under the motherboard corresponsive to the position of the central processing unit (CPU) and a heat sink disposed on the conductive member, so that the conductive member can rapidly transfer the heat source produced by the central processing unit (CPU) to the heat sink thereunder, and then the heat sink can effectively disperse the heat source.

### BRIEF DESCRIPTION OF THE DRAWINGS

To provide a further understanding of the invention, the following detailed description illustrates embodiments and examples of the invention, this detailed description being provided only for illustration of the invention.

FIG. 1 is a perspective diagram of the central processing unit (CPU) heat sink module of the present invention.

FIG. 2 is an illustrative diagram of a preferred embodiment of the present invention.

FIG. 3 is an illustrative diagram of another preferred embodiment of the present invention.

FIG. 4 is an illustrative diagram of another further preferred embodiment of the present invention.

### DETAILED DESCRIPTION OF THE PREFERRED EMBODIMENTS

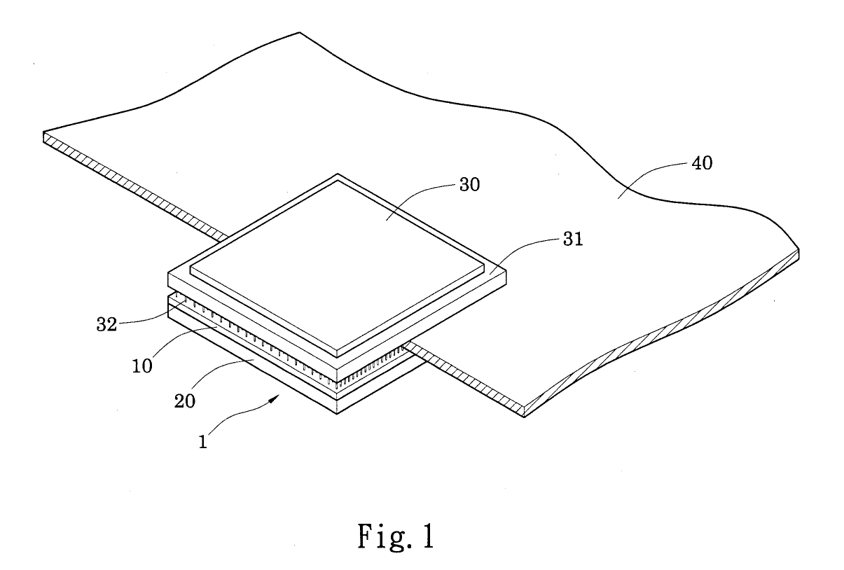

Please refer to FIG. 1 for a perspective diagram of the central processing unit (CPU) heat sink module of the present invention. The central processing unit (CPU) heat sink module according to the present invention as shown in the figure is disposed under a central processing unit (CPU) 30 and a motherboard 40, and said heat sink module 1 comprises a conductive member 10 disposed under the motherboard 40 corresponsive to the position of the central processing unit (CPU) 30, and a heat sink 20 disposed on the conductive member 10. The conductive member 10 could be a heat dispersion glue to facilitate the assembling by the user. Since the central processing unit (CPU) 30 is disposed on a socket 31 of the motherboard 40, the heat source produced at a contact end 32 under the socket 31 is rapidly transferred to the heat sink 20. The increased heat dispersion area of the heat sink 20 effectively disperses the heat source produced by the contact end 32 of the central processing unit (CPU) 30.

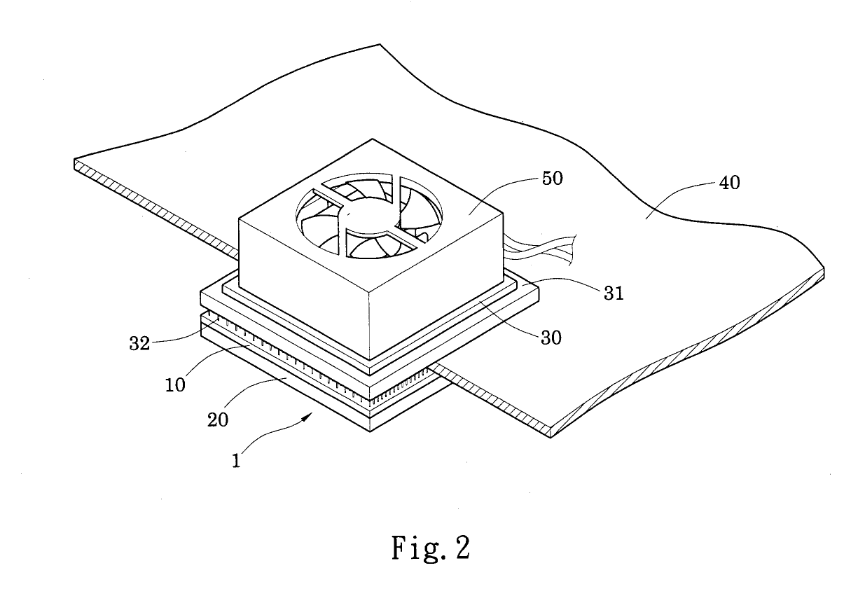

Please refer to FIG. 2 for an illustrative diagram of a preferred embodiment of the present invention. In the figure, besides having a conductive member 10 and a heat sink under a motherboard 40 corresponsive to the position of the central processing unit (CPU) 30, the present invention may also have a fan 50 disposed on the central processing unit (CPU) 30. The conductive member 10 and the heat sink 20 under the central processing unit (CPU) 30 disperses the heat source at the contact end 32, under the central processing unit (CPU) 30 and the socket 31, and then a fan 50 at the top of the central processing unit (CPU) 30 effectively blows the heat source away from the central processing unit (CPU) 30.

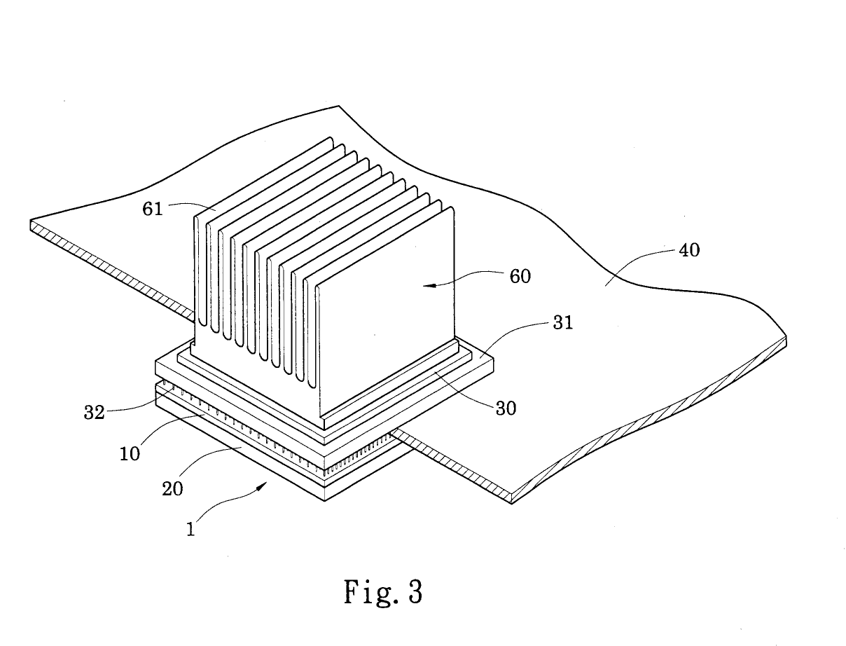

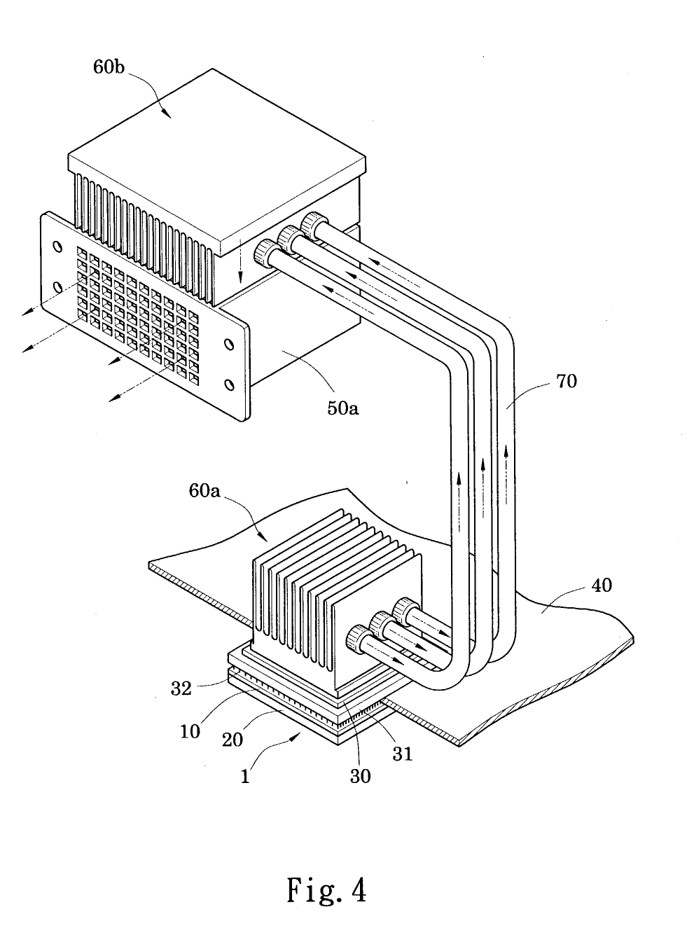

Please refer to FIGS. 3 and 4 for another two embodiments of the present invention. In the figures, besides having a conductive member 10 disposed under a motherboard 40 corresponsive to the position of a central processing unit (CPU) 30 and a heat sink 20, the present invention may also have a heat dispersion fin 60 disposed on the top of the central processing unit (CPU) 30. The heat source at the contact end 32 under the central processing unit (CPU) 30 and the heat sink 20 is dispersed by the conductive member 10 and the heat sink 20 under the central processing unit (CPU) 30. A plurality of parallel plates 61 of the heat dispersion fin 60 increase the heat dispersion area and effectively disperse the heat source at the top of the central processing unit (CPU) 30. In addition, a heat pipe 70 connects the heat dispersion fin 60a on the central processing unit (CPU) 30 to another heat dispersion fin 60b on a power supply or other component (not shown in the figure) to integrate the heat sources between components, and the heat is blown away by a fan 50a under the heat dispersion fin 60b. The present invention not only effectively disperses the heat source, but also greatly reduces the interior space of the housing of the computer.

In view of the description above, the present invention has the following advantages:

(1) The present invention utilizes a conductive member 10 (heat dispersion glue) and a heat sink 20 to rapidly disperse the heat source produced by the contact end 32 under the socket 31.

(2) The present invention utilizes a sheet heat dispersion glue but not the heat dispersion paste to facilitate the assembling.

(3) The present invention works together with a fan 50 on the central processing unit (CPU) 30 or a heat dispersion fin 60 to effective enhance the heat dispersion efficiency.

What is claimed is:

1. A central processing unit (CPU) heat sink module, disposed under a central processing unit (CPU) and a motherboard, comprising:
a conductive member, disposed under the motherboard and corresponsive to the central processing unit (CPU); and
a heat sink, disposed on the conductive member;
wherein said conductive member rapidly transferring a heat source produced by the central processing unit (CPU) to the bottom of said heat sink, and then said heat sink dispersing the heat source.

2. The central processing unit (CPU) heat sink module of claim 1, wherein said conductive member is a heat dispersion glue.

3. The central processing unit (CPU) heat sink module of claim 1, wherein said central processing unit (CPU) comprises a fan thereon.

4. The central processing unit (CPU) heat sink module of claim 1, wherein said central processing unit (CPU) comprises a heat dispersion fin thereon.

5. The central processing unit central processing unit (CPU) heat sink module of claim 4, wherein said heat dispersion fin is coupled to a heat pipe to centralize and eliminate the heat source produced by each component.
